(19) United States
(12) Patent Application Publication
(10) Pub. No.: US 2024/0109139 A1
(43) Pub. Date: Apr. 4, 2024

(54) PORTABLE SOLAR MODULE DEFRAMER

(71) Applicant: SOLARCYCLE, Inc., Odessa, TX (US)

(72) Inventors: Pablo RIBEIRO DIAS, Oakland, CA (US); Guilherme GEESDORF, Oakland, CA (US)

(21) Appl. No.: 18/451,709

(22) Filed: Aug. 17, 2023

Related U.S. Application Data
(60) Provisional application No. 63/412,307, filed on Sep. 30, 2022.

(51) Int. Cl. B23D 1/08; H01L 31/18

(52) U.S. Cl. CPC B23D 1/08; H01L 31/18

(57) ABSTRACT

Embodiments relate to methods and apparatuses that remove a frame from a solar module in order to facilitate its recycling. Such a deframer may feature one or more characteristics to promote its portability (e.g., to a site of former installation of the used module). Such characteristics can include but are not limited to: having certain components (e.g., moveable protection doors) formed from lighter-weight aluminum; and having retractable legs to enhance its compact size in a transport configuration (e.g., in a trailer or on the back of a truck). In some embodiments a module deframer may employ a cutting system to remove junction box(es) from a PV module. Such a cutting system may use a single cut motion that is adjustable.

### CROSS-REFERENCE TO RELATED APPLICATION

The instant nonprovisional patent application claims priority to U.S. Provisional Patent Application No. 63/412,307, filed Sep. 30, 2022 and incorporated by reference in its entirety herein for all purposes.

### BACKGROUND

A solar module may comprise photovoltaic (PV) material positioned within a frame, which may comprise aluminum or other material(s). A solar module may further comprise a junction box housing conductors to convey electrical current collected from the PV material. It may be desirable to recycle and/or refurbish PV modules.

### SUMMARY

Embodiments relate to methods and apparatuses that remove a frame from a solar module in order to facilitate its recycling. Such a deframer may feature one or more characteristics to promote portability (e.g., to a site of former installation of the used module). Such characteristics can include, but are not limited to: having certain components (e.g., moveable protection doors) formed from lighter-weight aluminum, and having retractable leg(s) to reduce space occupied in a transport configuration (e.g., within a trailer or on the back of a truck). In some embodiments a module deframer may employ a cutting system to remove junction box(es) from a PV module. Such a cutting system may use a single cut motion that is adjustable.

### BRIEF DESCRIPTION OF THE DRAWINGS

FIG. 1 shows a simplified view of a deframer located in the back of a truck.

FIG. 2 shows an enlarged view of a deframer embodiment in a transport configuration.

FIG. 3 shows an isometric view of the deframer in the transport configuration.

FIG. 4 shows a side view of the deframer.

FIG. 5 shows a first detail A.

FIG. 6 shows a second detail B.

FIG. 7 shows an isometric view of the deframer in the ground use configuration.

FIG. 8 shows a side view of the deframer.

FIG. 9 shows a third detail C.

FIG. 10 shows an isometric view of a first (“Single”) element of the deframer.

FIG. 11 shows a top view of the first element.

FIG. 12 shows a side view of the first element.

FIG. 13 shows an end view of the first element.

FIG. 14 shows an isometric view of a second (“Double”) element of the deframer.

FIG. 15 shows an end view of the second element.

FIG. 16 shows a side view of the second element.

FIG. 17 shows a top view of the second element.

FIG. 18 is a side view of the portable deframer embodiment in the ground use configuration.

FIG. 19 is a top view of the portable deframer embodiment in the ground use configuration.

FIG. 20 is an isometric view of the portable deframer embodiment in the ground use configuration.

FIG. 21 shows a cross-sectional view of a monofacial solar module according to an example.

FIG. 21A shows a simplified overhead view of the laminate of a solar module, lacking the frame and the top transparent sheet.

FIG. 22 shows a perspective view of a deframer embodiment in a use configuration with a protection door shut.

FIG. 22A shows a perspective view of a deframer embodiment in the use configuration with the protection door open.

FIG. 22B shows a side view of the portable deframer.

FIG. 22C shows an enlarged view of one detail of the portable deframer embodiment of FIG. 22.

FIG. 22D shows an enlarged view of another detail of the portable deframer embodiment of FIG. 22.

### DESCRIPTION

Solar modules exist in a variety of types and architectures. Examples of such modules can include but are not limited to:
Monocrystalline Solar Panels (Mono-SI)
Polycrystalline Solar Panels (p-Si)
Amorphous Silicon Solar Panels (A-SI)
Cadmium telluride photovoltaics (CdTe)
Copper indium gallium selenide modules (CIGS)
Copper indium selenide modules (CIS)
Concentrated PV Cell (CVP)
Biohybrid Solar modules
Monofacial modules
Bifacial modules
Modules without encapsulant
Silicon heterojunction solar modules
tunnel oxide passivated contact solar modules (TOPCON)
passivated emitter and rear contact solar modules (PERC)
Tandem-junction Solar Panels
Perovskite-based Solar Panels
Glass-Backsheet Solar Panels
Glass-Glass Solar Panels
Building-Integrated Solar Panels
Polymer-Based Solar Panels
Solar Roof Tiles
Solar Roof Shingles

Solar modules can last decades, with some degradation in performance over a module's lifetime. Also, solar modules that have been deployed on residential rooftops and other commercial and utility-scale applications for a number of years, may be decommissioned for a variety of reasons.

For example, (residential, commercial, utility) users of solar panels may desire to exchange their modules for newer, higher performing modules in order to maximize the amount of energy obtained from a solar array.

As more solar modules reach the end of their useful lives and/or are relinquished by their owners, it is desirable to dispose of the panels in an environmentally-friendly and economically-feasible way. Alternatively, it may be desired to refurbish and reuse existing solar modules to prolong their lifetimes and reduce cost.

Once it is determined that a solar module is no longer useful to its owner, e.g.:
the module has reached the end of its current deployment due to non- or underperformance,
the module has been damaged in transit, or
for other (e.g., economic) reasons,
   in order to avoid discarding the module into a landfill, the module may either be recycled or refurbished and reused.

Accordingly, to determine whether a solar module should be recycled or refurbished and reused, embodiments may implement one or more of the following processes, alone or in various combinations and sequences.
cleaning;
inspection to determine reusability;
testing;
remove cabling;
remove frames surrounding the panel and/or junction boxes (either manually, or e.g., using an automated deframing machine).
transparent front layers and potentially other layers (e.g., the backsheet) may be removed using a delamination process.

Remaining layers (of, e.g., a laminate) may be shredded. Shredded materials can be separated using one or more processes in order to extract various possible reusable materials therefrom (e.g., valuable commodity metals such as silicon, silver, and/or copper).

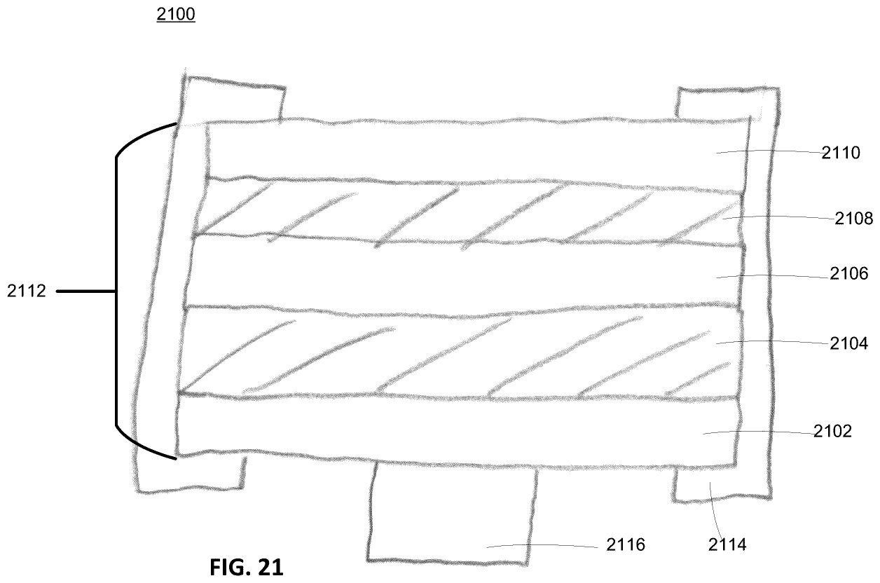

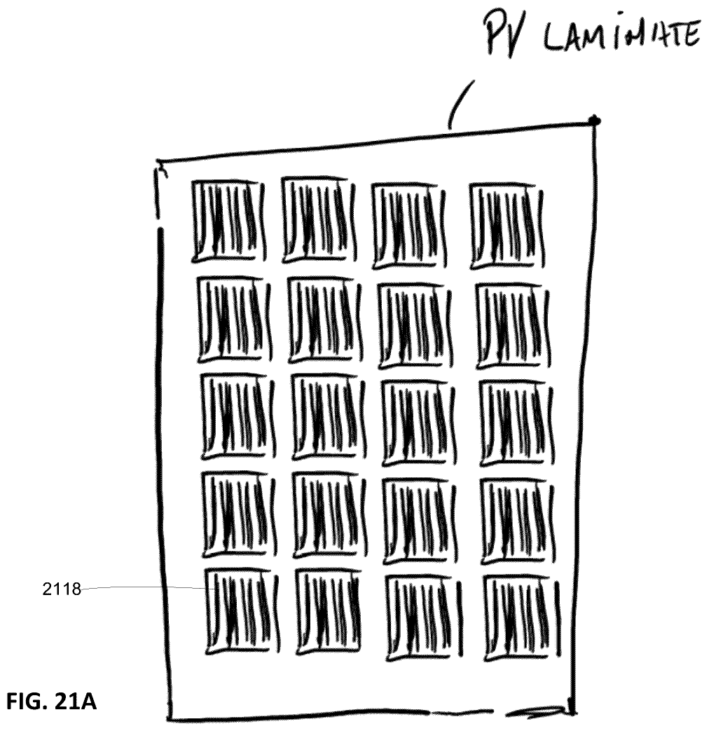

Embodiments relate to various techniques that may be employed, alone or in combination, for the recycling and/or refurbishment of solar modules. FIG. 21 shows a cross-sectional view of a monofacial solar module according to an example.

The PV module 2100 is made of different layers assembled into the structure shown in FIG. 21. These layers of FIG. 21 are not drawn to scale.

The layers of FIG. 21 can be simplified as:
substrate (backsheet) 2102,
back encapsulant 2104, e.g., Ethylene-vinyl acetate (EVA), silicone, Polyvinyl butyral (PVB), IONOMER,
solar cell 2106 comprising PV material (including, e.g., but not limited to: doped single crystal, polycrystalline, or amorphous silicon, Group III-V materials) and metallization,
front encapsulant 2108,
transparent front cover sheet 2110 (e.g., typically glass).
   This grouping of layers is referred to as a laminate 2112.

It is further noted that bifacial modules also exist. Such bifacial modules may exhibit a structure similar to that of FIG. 21, but have a transparent (e.g., glass) layer instead of a backsheet layer. This allows (e.g., reflected) light to enter the module from the back.

The laminate in FIG. 21 is surrounded by a frame 2114. The frame may comprise a stiff metal such as aluminum. Alternatively, a frame material may be plastic, comprising e.g., polycarbonate.

A junction box 2116 is also part of the module. The junction box may be potted (more common in newer models) or non-potted (more common in older models). In a the potted PV junction box, the foils coming out of the solar panel are soldered to the diodes in the junction box, and the junction box is potted or filled with a type of sticky material to allow thermal transfer of heat to keep the solder joint in place and prevent it from falling. Fabrication may take longer but creates a better seal.

In the non-potted PV junction box, a clamping mechanism is used to attach the foil to the wires in the junction box. This can involve a faster assembly, but may not be as robust. A module having a potted junction box may be more amenable to recycling or refurbishment.

FIG. 21A shows a simplified overhead view of the laminate of a solar module, lacking the frame and the top transparent sheet. FIG. 21A shows solar cells including patterned metallization 2118, which may comprise, e.g., a valuable metal such as silver.

Prior to delamination, the frame may be removed. Embodiments relate to a portable deframer for solar modules.

Such a mobile deframer may perform at least one, and possibly both, of the following functions:
remove an (aluminum) frame from a photovoltaic (PV) modules;
separate junction box(es) from the PV module.

Embodiments of a portable deframer may exhibit high throughput. Particular embodiments may be able to process 80 panels or more per hour.

Module deframer embodiments may be mobile. That is, the deframer can readily be transported and located at a particular point in a solar module recycling process.

A portable deframer may feature one or more components made out of aluminum rather than steel. For example, in certain embodiments the interior of the machine comprising the main components for deframing may be steel, while moveable protection door(s) could be aluminum.

The use of lighter-weight materials can reduce the weight of the apparatus and facilitate its portability. As a result the deframer is easier to maneuver/manipulate by a limited number of operators (e.g., two), and fuel consumption is reduced to transport the portable deframer to different locations (e.g., past, or future sites for installing solar modules).

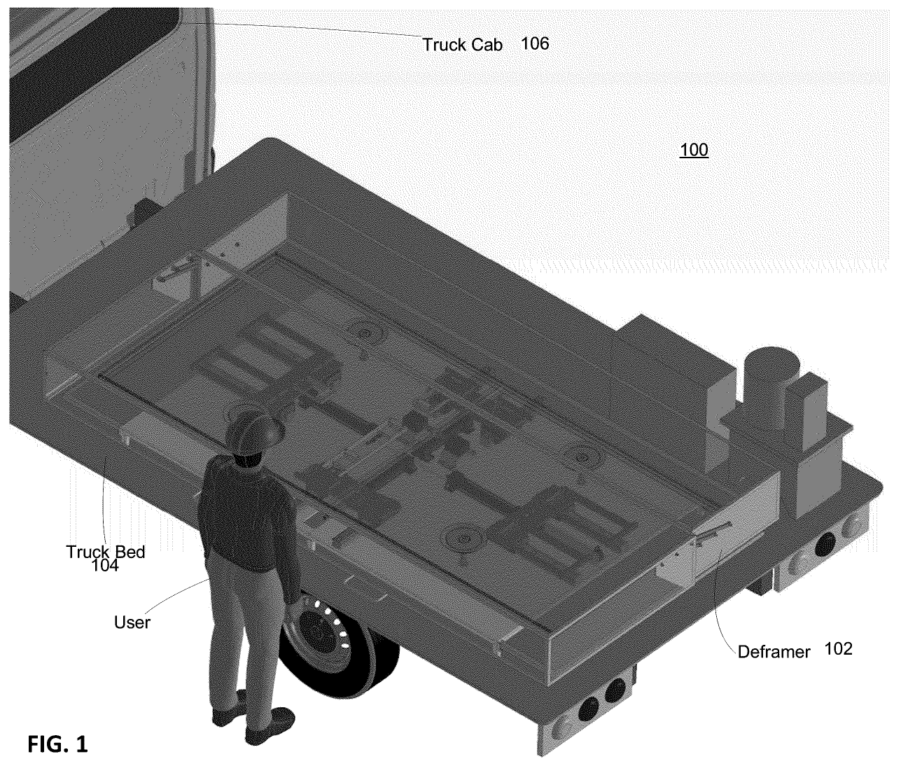

Portable deframer embodiments are compact and lightweight enough to be positioned in a back of a vehicle (such as a splinter van). FIG. 1 shows a simplified view 100 of a deframer 102 located in the back 104 of a truck 106.

Portable deframer embodiments are also robust enough to be deployed as stationary machinery in a warehouse.

The equipment features foldable legs that allows it to be mounted on the ground or to be retracted to decrease the volume and place it in the back of a transport vehicle.

The equipment design was optimized so that it can go on the back of a big transport vehicle or on the back of a smaller vehicle (e.g. Splinter van). It was designed in a way that the equipment rests mainly on the vehicle chassis so that the load is evenly distributed on the vehicle.

A portable deframer embodiment may employ a cutting system to remove the junction box. Such a cutting system may use a single cut motion and that is adjustable.

Positioning of the cutting system may have freedom to move on both axes (−x, x, −y, y) of the length and width of the module. The cutting system may reach various parts of the back of the PV module.

The cutting mechanism may be coupled to the same movement system of the cylinders. Additionally, the cutting mechanism may self-align on the surface of the module (z axis), by a spring system that ensures the cutting mechanism is flush with the panel surface. The spring may bias the cutting device against the surface of the module.

Adjustability in cutting motion may desirably accommodate removal of junction boxes that have been placed in different parts of the PV modules. In some embodiments, a portable deframer may remove a junction box as a single piece.

A portable deframer may use a motor that is powered by a wall outlet in a warehouse or factory. A portable deframer motor may also be used with a generator that provides power in the field where no power outlets may be available.

A portable deframer may exhibit an adjustable physical profile. In this manner the deframer can defame small (e.g. residential) modules, as well as larger (e.g. utility-scale) modules. Particular deframer embodiments may accommodate modules having dimensions as large as 2716 mm×1098 mm, but embodiments are not limited to handling modules of that or any other particular size.

A deframer according to embodiments may be capable of keeping solar glass intact after the removal of the junction box and frame (deframing process). This can be desirable in that solar glass may be manufactured to exacting optical and physical requirements, and hence expensive to replace.

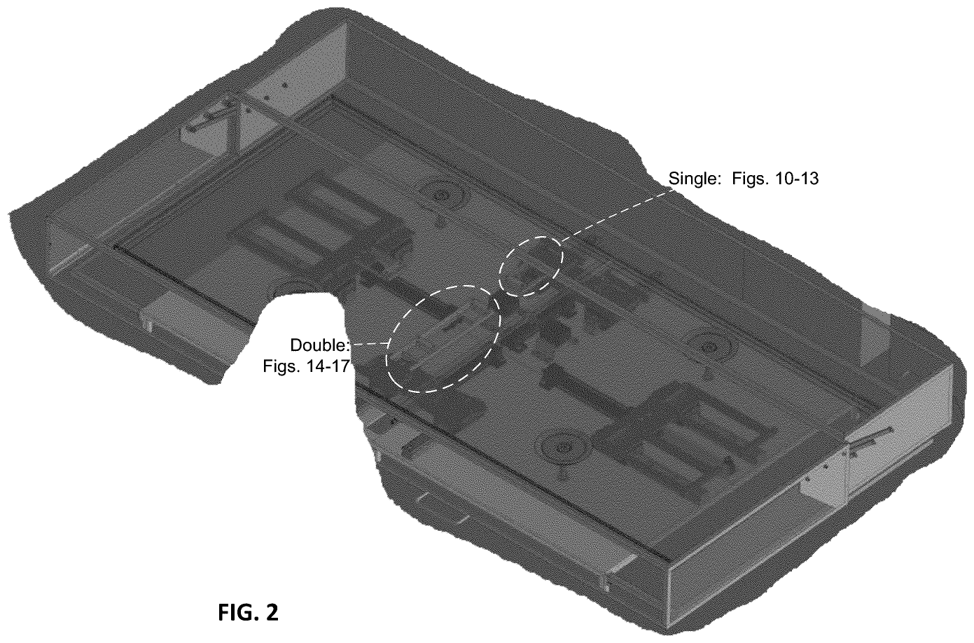

FIG. 2 shows an enlarged view of a deframer embodiment in a transport configuration. Here, both doors are closed.

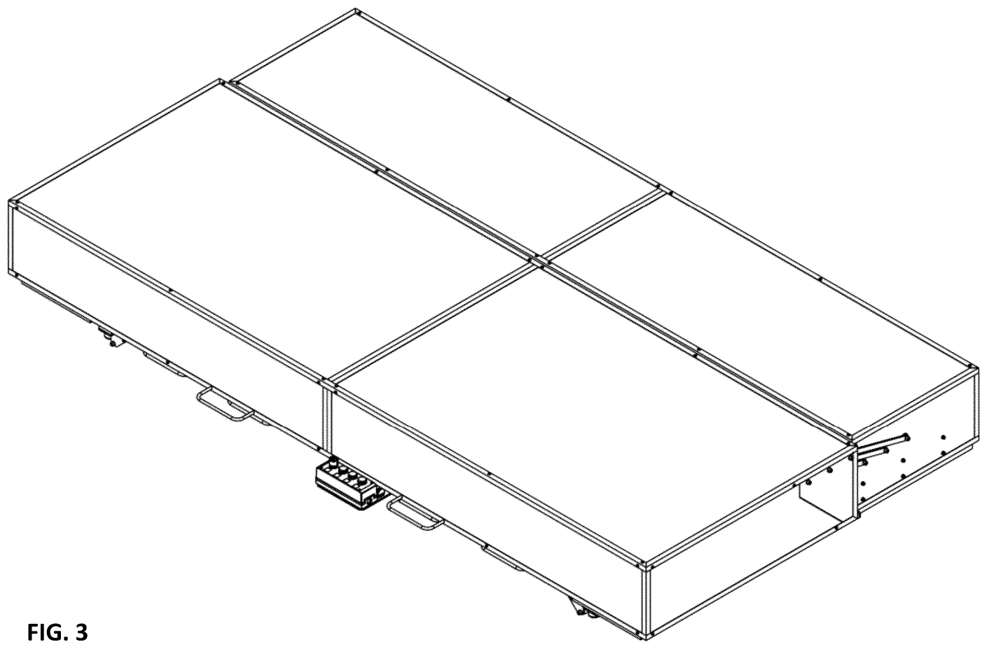

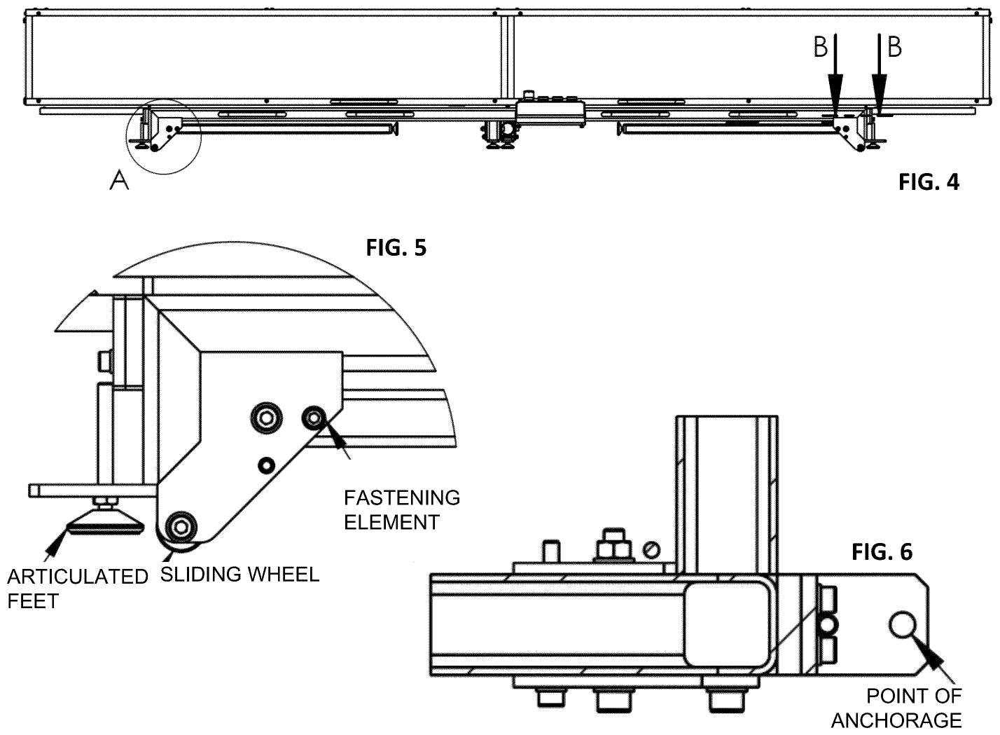

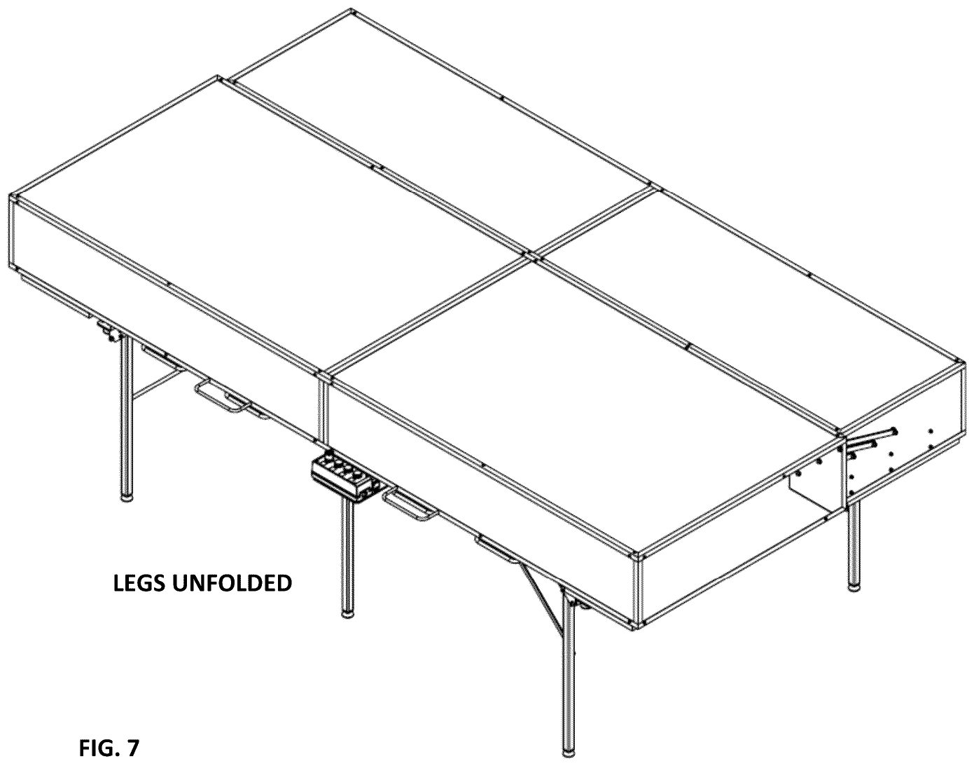

FIG. 3 shows an isometric view of the deframer in the transport configuration. FIG. 4 shows a side view of the deframer. FIG. 5 shows a first detail A. FIG. 6 shows a second detail B.

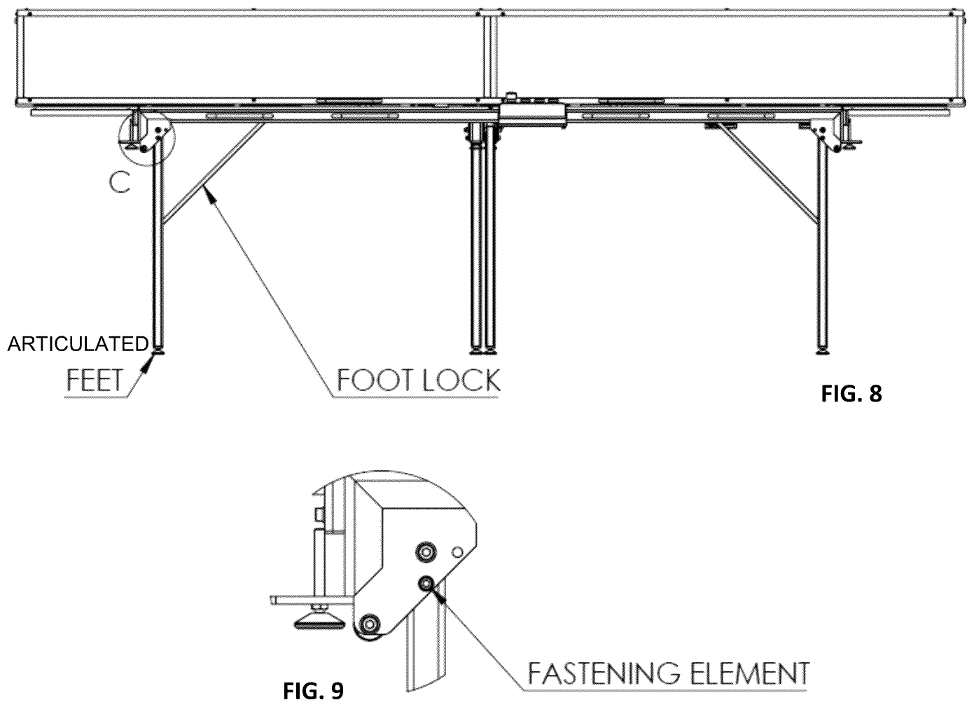

FIG. 7 shows an isometric view of the deframer in the ground use configuration. FIG. 8 shows a side view of the deframer. FIG. 9 shows a third detail C.

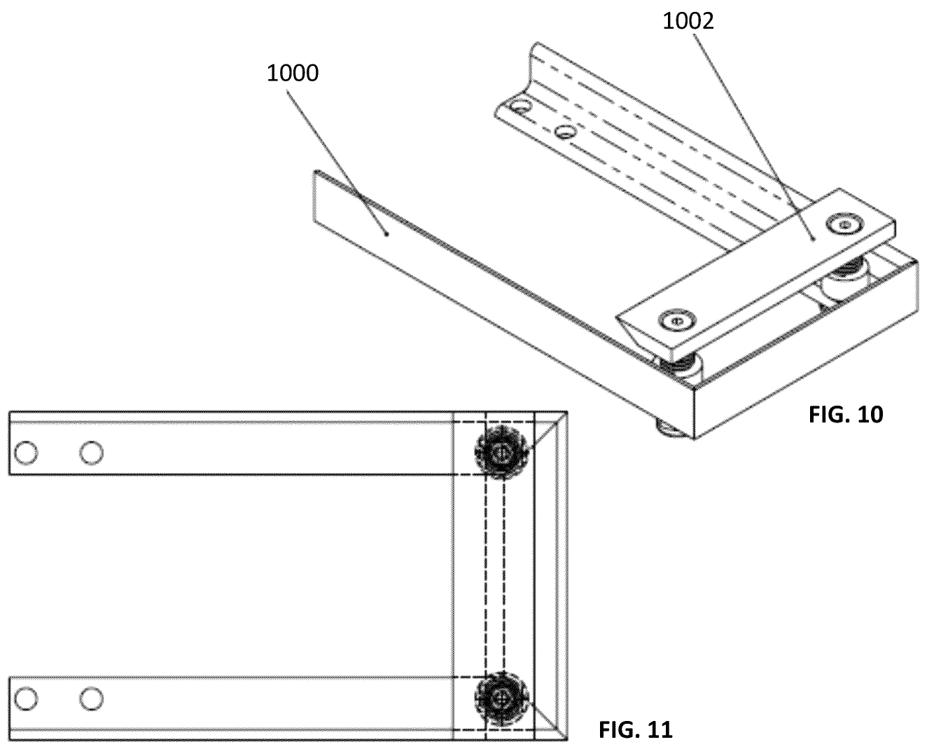

FIG. 10 shows an isometric view of a first (“Single”) element of the deframer that is used for removing a junction box. The reference number 1000 shows the structure of the junction box remover. The reference number 1002 shows the blade of the single junction box remover.

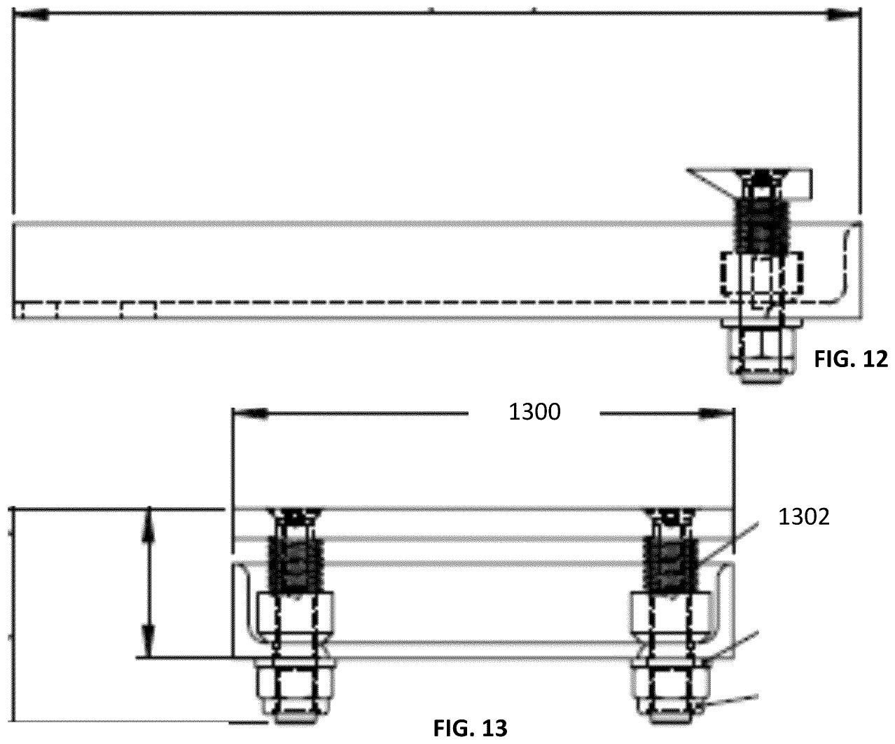

FIG. 11 shows a top view of the first element. FIG. 12 shows a side view of the first element.

FIG. 13 shows a front view of the first element of a single junction box remover 1300. The reference no. 1302 shows the spring system of the single box remover that makes the blade flush with the PV panel so as to ensure the cut is smooth and aimed at the interface between the junction box and panel.

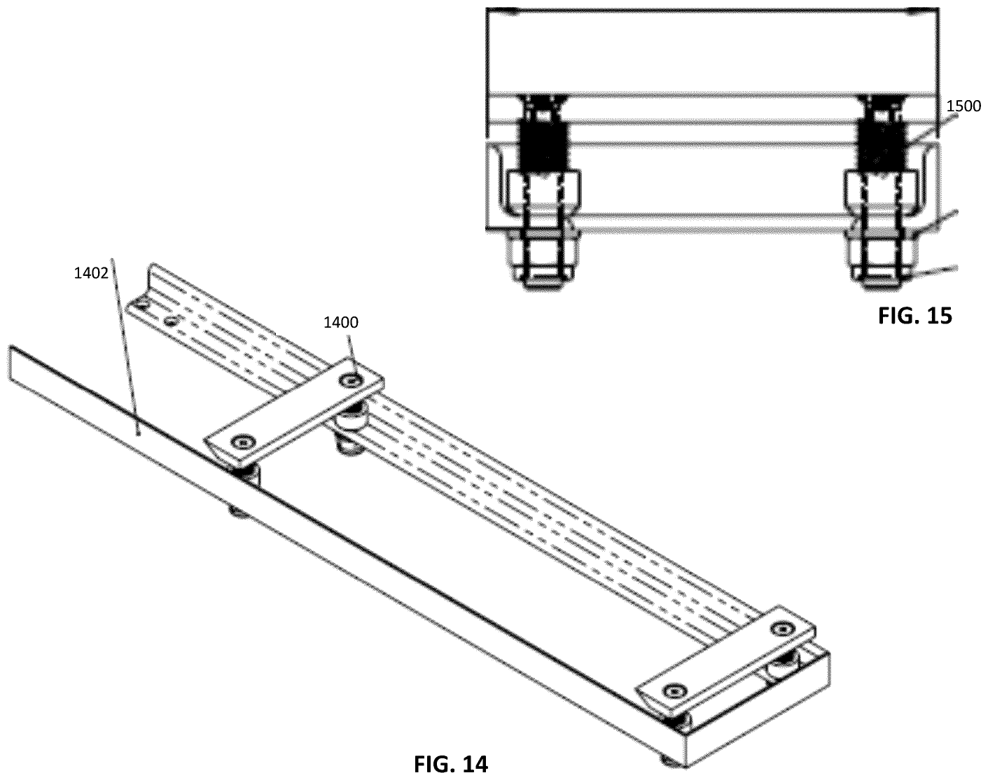

FIG. 14 shows an isometric view of a second (“Double”) element 1400 of the deframer. The reference no. 1400 shows one of the blades of the double junction box remover. Springs press against the body of the module and ensure that the blade will cut off the junction box at the correct spot.

FIG. 15 shows an end view of the second element. The reference no. 1500 shows the springs.

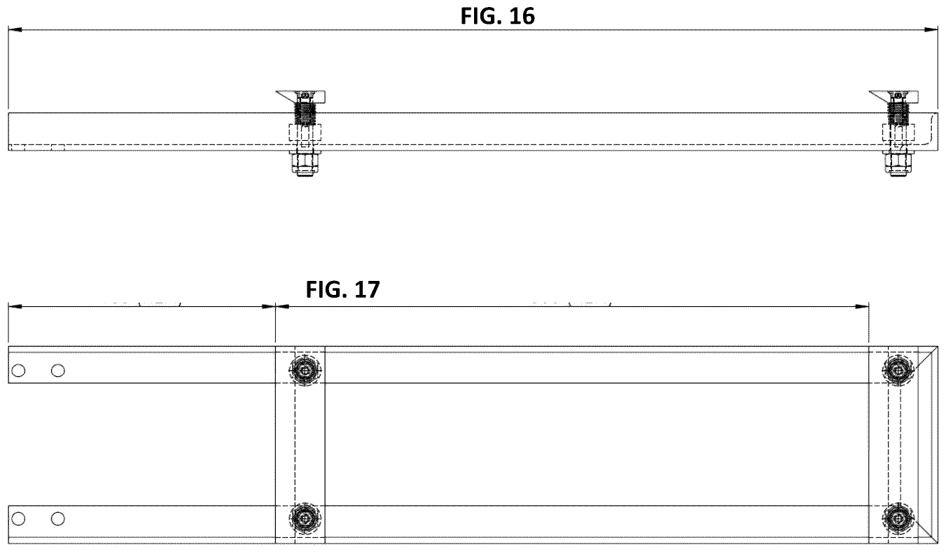

FIG. 16 shows a side view of the second element. FIG. 17 shows a top view of the second element.

The first, single element is a cutting mechanism for when a module only has one junction box (i.e, there is only one cutter). The second, double mechanism is used when the panel has multiple junction boxes along a same axis.

The double mechanism allows removal of multiple junction boxes with a single movement, because it has two cutters. This speeds up the process by not requiring a single cutter to travel a greater distance.

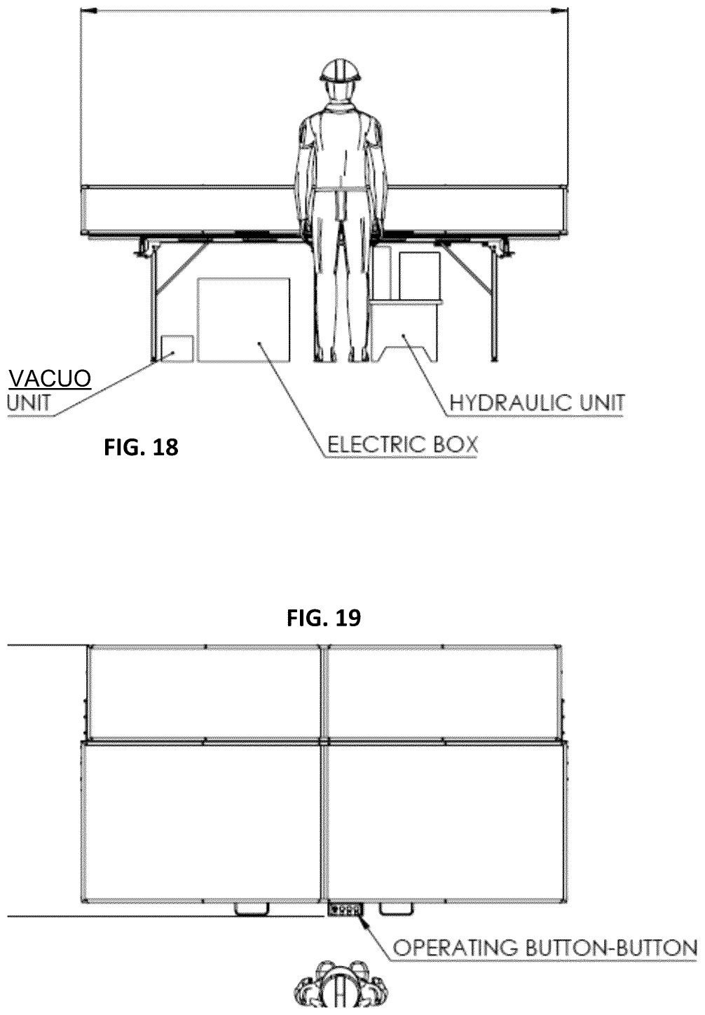

FIG. 18 is a side view of the portable deframer embodiment in the ground use configuration. FIG. 19 is a top view of the portable deframer embodiment in the ground use configuration.

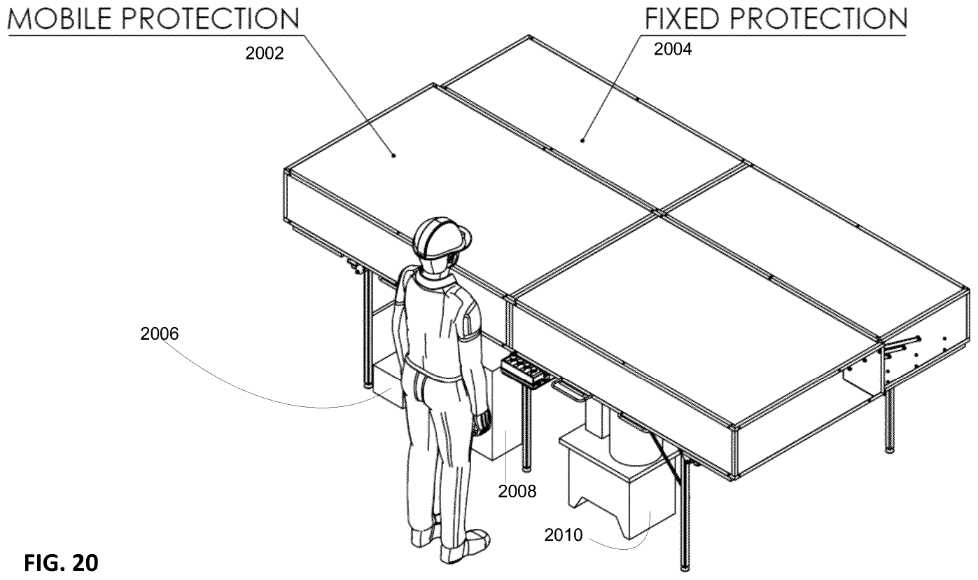

FIG. 20 is an isometric view of the portable deframer embodiment in the ground use configuration. Both mobile protection 2002 and fixed protection 2004 are shown. Also shown are vacuo unit 2006, electric box 2008, and hydraulic unit 2010.

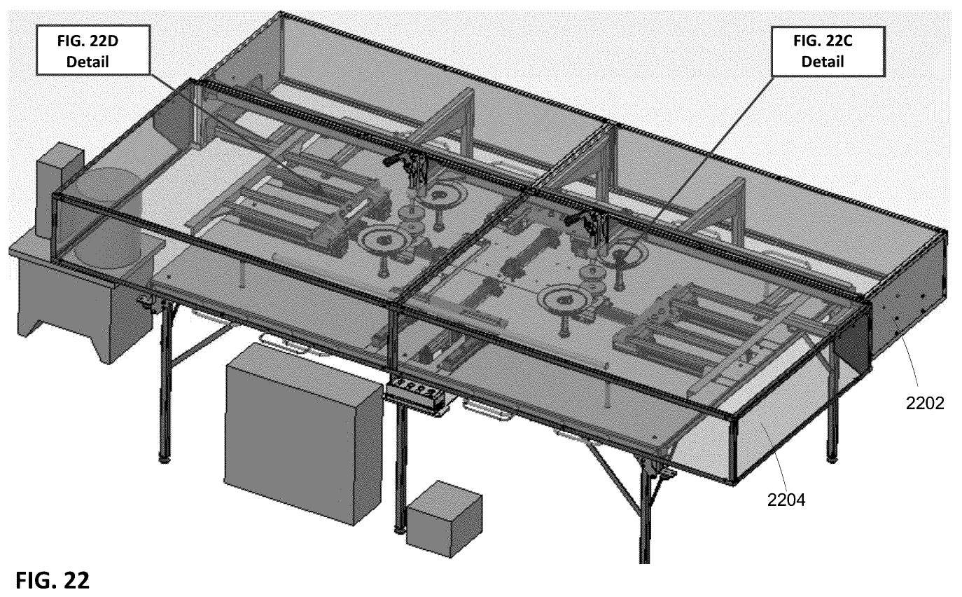

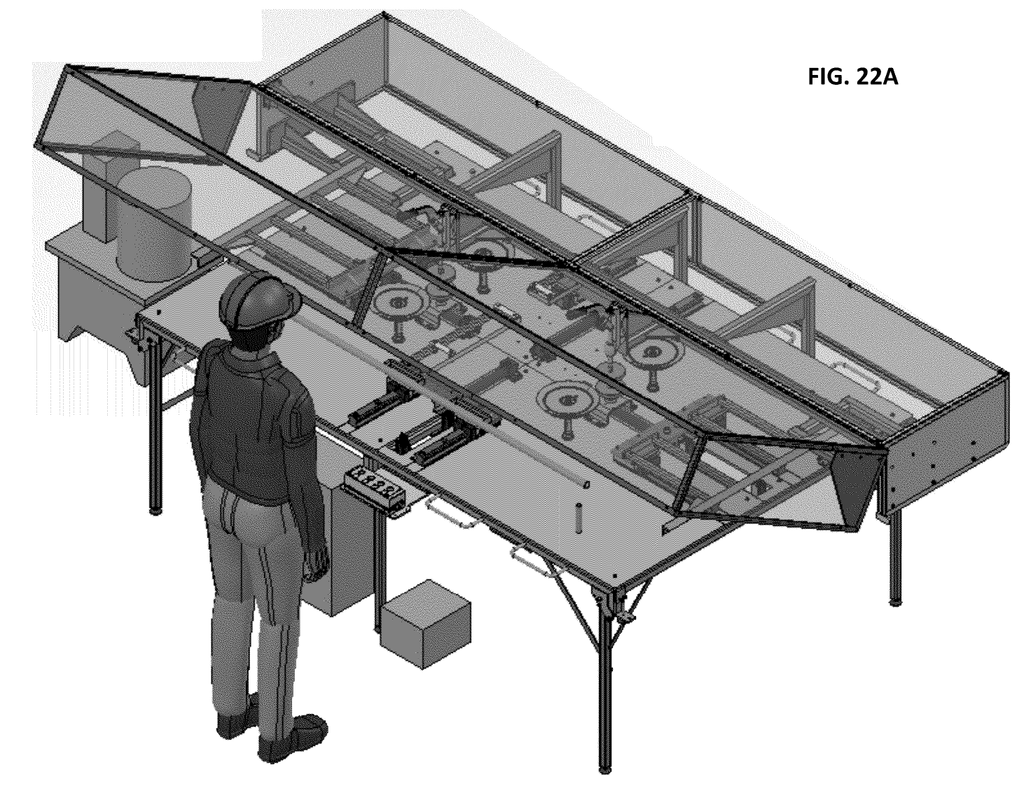

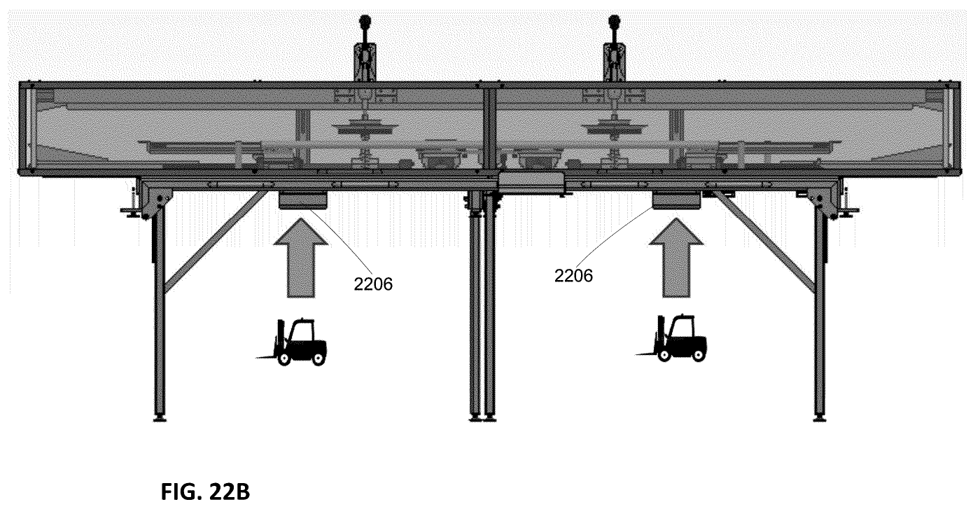

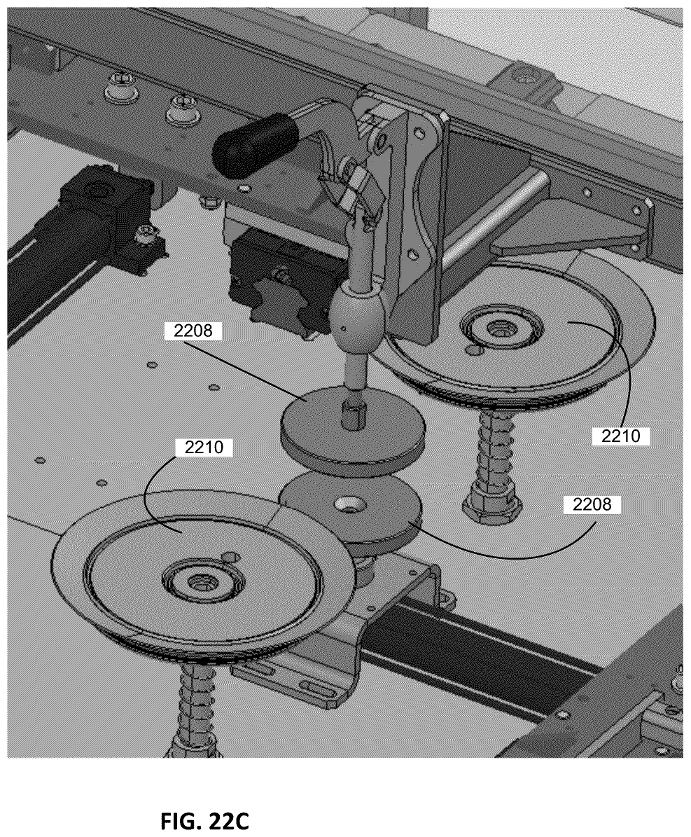

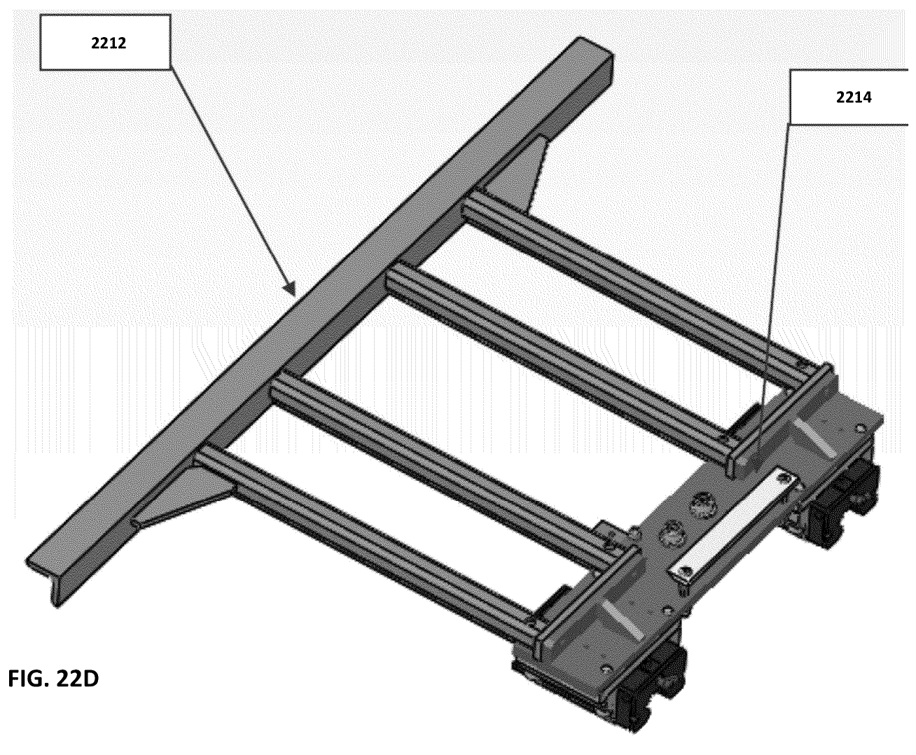

FIG. 22 shows a perspective view of another embodiment of a deframer in an operation configuration. Here, the mobile protection door is closed.

Specifically, these are two parts of the protection so that aluminum frames cannot fly towards the operator. This is done by enclosing the equipment during operation.

The fixed portion 2202 does not move, i.e., is always in the same position. The mobile portion is 2204 lifted, and opens upwards like a door with two pistons holding it up, as is shown in FIG. 22A. This allows the operator to access the panel inside the machine to remove the panel that has been deframed, and place a new panel for deframing.

FIG. 22B shows a side view of the deframer embodiment. Here, metal bumpers 2206 protect equipment from forklift damage. The bumpers also signal where a forklift should suspend equipment.

FIG. 22C shows a detail of the portable deframer embodiment of FIG. 22. This view shows a pressing system 2208 that helps to fix the photovoltaic panel in place.

Suction cups 2210 are also shown in FIG. 22C. In certain embodiments, the solar module may be held in place by suction cups for deframing and/or junction box removal operations. The use of suction cups may afford a solid grip upon the component, and allows for the removal of the frames by applying force.

The use of suction for gripping may also aid in lightening the equipment, as a limited number (e.g., 2-6 suction cups) may be needed to hold the module. Moreover, the use of suction gripping may permit the deframer equipment to operate to deframe and/or remove the junction box, from solar modules that are broken (e.g., which have shattered glass and/or missing pieces). Thus the suction system can employ vacuum and/or specially designed cups that exhibit a strong grip in uneven or dirty surfaces.

FIG. 22D shows another detail of the portable deframer embodiment of FIG. 22. This view shows a displacement system 2212 for larger plates with reinforced tooling. FIG. 22D also shows a larger knife 2214 to remove the junction box positioned at the center on the end of the smaller side.

It is noted that a portable deframer may be of particular use for recycling/refurbishing solar modules directly at a site of installation. For example, the glass could be separated from the rest of the panel on the field using a mobile separator.

This could be accomplished using a delaminator and/or glass grinder machine that can grind with precise thickness and thus target the glass exclusively. Potential benefits of such an approach is an ability to leverage an existing glass supply chain close to the site in which the panels are located. This can also decrease emissions and cost associated with shipping glass long distances. Embodiments may also facilitate transporting more laminates (panels without frames, junction boxes, or glass) per truckload than would be otherwise possible with the glass.

Furthermore, the laminates themselves (e.g., modules without frames, junction box, or glass) may be separated in the field using a mobile device. Such a device may separate plastics from other materials (e.g., silicon, silver, copper, aluminum, lead, tin). Potential advantages are again the ability to leverage an existing plastic supply chain close to the site in which the panels are located, or send them to nearby landfill.

Such embodiments can also desirably decrease emissions and cost associated with shipping plastic long distances. Embodiments may also facilitate the transport of more valuable materials (silicon, silver, copper, aluminum, lead, tin) per truckload than would be otherwise possible with the plastics. Embodiments may also facilitate transport using different configuration/modes, given that valuable materials (e.g., silicon, silver, copper, aluminum, lead, tin) are now present in powder form rather than bulky laminate form.

Clause 1A. A method comprising:
receiving a portable solar module deframer in a transport configuration having a leg retracted;
extending the leg to convert the portable deframer into a ground use configuration;
connecting a motor of the portable deframer to a power source;
feeding a solar module including a frame into the portable deframer; and
causing the portable deframer to remove the frame.

Clause 2A. A method as in Clause 1A wherein the power source comprises a wall outlet.

Clause 3A. A method as in Clause 1A wherein the power source comprises a generator.

Clause 4A. A method as in any of Clauses 1A, 2A, or 3A wherein the frame has dimensions of 2716 mm×1098 mm or less.

Clause 5A. A method as in any of Clauses 1A, 2A, 3A, or 4A wherein the portable deframer comprises steel and the leg comprises aluminum.

Clause 6A. A method as in any of Clauses 1A, 2A, 3A, 4A, or 5A wherein the portable deframer is received at a past solar module installation site.

Clause 7A. A method as in any of Clauses 1A, 2A, 3A, 4A, or 5A wherein the portable deframer is received at a future solar module installation site.

Clause 8A. A method as in any of Clauses 1A, 2A, 3A, 4A, 5A, 6A, or 7A further comprising the portable deframer removing a junction box from the solar module.

Clause 9A. A method as in Clause 8A further comprising the portable deframer removing the junction box in a single cutting motion.

Clause 10A. A method as in Clause 9A wherein the junction box is at a first location of the solar module, the method further comprising:
feeding another solar module including another frame and another junction box at a different location, into the portable deframer; and
causing the portable deframer to remove the another junction box.

Clause 1B. An apparatus comprising: a portable deframer comprising a first material and having a leg comprising a second material extendable from a transport configuration into a ground use configuration.

Clause 2B. An apparatus as in Clause 1B wherein the first material is steel and the second material is aluminum.

Clause 3B. An apparatus as in any of Clauses 1B or 2B positioned in a truck bed.

Clause 4B. An apparatus as in any of Clauses 1B, 2B, or 3B comprising a vacuum system.

Clause 5B. An apparatus as in any of Clauses 1B, 2B, 3B, or 4B comprising a suction cup.

Clause 6B. An apparatus as in any of Clauses 1B, 2B, 3B, 4B, or 5B comprising:
a single cutter configured to access a back of a module; and
a double cutter configured to separate a second junction box located along a same axis with a first junction box.

What is claimed is:

1. A method comprising:
receiving a portable solar module deframer in a transport configuration having a leg retracted;
extending the leg to convert the portable deframer into a ground use configuration;
connecting a motor of the portable deframer to a power source;
feeding a solar module including a frame into the portable deframer; and
causing the portable deframer to remove the frame.

2. A method as in claim 1 wherein the power source comprises a wall outlet.

3. A method as in claim 1 wherein the power source comprises a generator.

4. A method as in claim 1 wherein the frame has dimensions of 2716 mm×1098 mm or less.

5. A method as in claim 1 wherein the portable deframer comprises steel and the leg comprises aluminum.

6. A method as in claim 1 wherein the portable deframer is received at a past solar module installation site.

7. A method as in claim 1 wherein the portable deframer is received at a future solar module installation site.

8. A method as in claim 1 further comprising the portable deframer removing a junction box from the solar module.

9. A method as in claim 8 further comprising the portable deframer removing the junction box in a single cutting motion.

10. A method as in claim 9 wherein the junction box is at a first location of the solar module, the method further comprising:
feeding another solar module including another frame and another junction box at a different location, into the portable deframer; and
causing the portable deframer to remove the another junction box.

11. An apparatus comprising:
a portable deframer comprising a first material and having a leg comprising a second material extendable from a transport configuration into a ground use configuration.

12. An apparatus as in claim 11 wherein the first material is steel and the second material is aluminum.

13. An apparatus as in claim 11 positioned in a truck bed.

14. An apparatus as in claim 11 comprising a vacuum system.

15. An apparatus as in claim 11 comprising a suction cup.

16. An apparatus as in claim 11 comprising:
a single cutter configured to access a back of a module; and
a double cutter configured to separate a second junction box located along a same axis with a first junction box.

17. An apparatus as in claim 11 comprising a first blade of a single junction box remover.

18. An apparatus as in claim 17 comprising second and third blades of a double junction box remover.

19. An apparatus as in claim 17 wherein the single junction box remover comprises a spring.

20. An apparatus as in claim 11 further comprising a pressing system configured to engage a surface of a used photovoltaic module.
